(19) United States
(12) Patent Application Publication
(10) Pub. No.: US 2025/0046645 A1
(43) Pub. Date: Feb. 6, 2025

(54) SUBSTRATE TREATMENT DEVICE, SUBSTRATE TREATMENT SYSTEM, AND METHOD FOR ALIGNING PLACEMENT TABLE

(71) Applicant: Tokyo Electron Limited, Minato-ku, Tokyo (JP)

(72) Inventors: Tamihiro KOBAYASHI, Fuchu City, Tokyo (JP); Takayuki YAMAGISHI, Fuchu City, Tokyo (JP)

(21) Appl. No.: 17/431,995

(22) PCT Filed: Feb. 14, 2020
(86) PCT No.: PCT/JP2020/005865

§ 371 Date: Aug. 18, 2021

(30) Foreign Application Priority Data
Feb. 27, 2019 (JP) 2019-034320
Jul. 12, 2019 (JP) 2019-130348

(51) Int. Cl. H01L 21/687; C23C 16/505; C23C 16/52; H01L 21/67; H01L 21/677; H01L 21/68

(52) U.S. Cl. CPC H01L 21/6875; C23C 16/505; C23C 16/52; H01L 21/67017; H01L 21/67282; H01L 21/67745; H01L 21/681

(57) ABSTRACT

A substrate processing apparatus includes stages each placing a substrate thereon, support columns supporting the stages, a common base supporting the support columns, and a position adjustment mechanism provided between the base and each support column. The position adjustment mechanism includes: a fixed member on a side of the base; a position adjustment member disposed above the fixed member and adjusting a position of the stage by positioning a base end portion of the support column; and gap height adjustment parts provided at at least three positions surrounding the support column, and mounting the position adjustment member to the fixed member in a state where a gap height between the fixed member and the position adjustment member is adjustable. At least one position adjustment mechanism is provided with a fixedly mounting part mounting the position adjustment member to the fixed member in a state where the gap height is fixed.

### TECHNICAL FIELD

The present disclosure relates to a substrate processing apparatus.

### BACKGROUND

In a semiconductor device manufacturing process, various processes such as film formation and etching are performed by supplying various processing gases to a semiconductor wafer (hereinafter, referred to as a “wafer”) which is a substrate. Such types of substrate processing may be performed in a state in which a stage is disposed in a processing container and a substrate is placed on the stage.

For example, Patent Document 1 describes a technique for adjusting a position of a fixing base provided on a twin dresser for forming a grooving grindstone, and Patent Document 2 describes a technique for horizontally moving a mold push plate used for press molding of an optical lens. In addition, Patent Document 3 describes a technique for positioning a screen plate for screen printing.

However, these patent documents do not describe a technique for adjusting a position of a stage used for substrate processing.

### PRIOR ART DOCUMENTS

### Patent Documents

Patent Document 1: Japanese Laid-Open Patent Publication No. 2011-161621
Patent Document 2: Japanese Laid-Open Patent Publication No. 2009-241464
Patent Document 3: Japanese Laid-Open Patent Publication No. 2002-53328

The present disclosure provides a substrate processing apparatus capable of relatively easily adjusting a position of a stage.

### SUMMARY

A substrate processing apparatus of the present disclosure is a substrate processing apparatus for processing a substrate by supplying a processing gas to the substrate, and includes: a plurality of stages which is disposed in a processing container and on each of which a substrate to be processed is placed; a plurality of support columns configured to support the plurality of stages from bottom surfaces of the stages, respectively, and penetrating a bottom surface of the processing container so as to protrude downward from the bottom surface of the processing container; a common base configured to support the plurality of support columns from base ends of the support columns; and a plurality of position adjustment mechanisms. Each of the position adjust mechanisms includes: a fixed member provided between the base and the base end of each of the support column and fixed to the base; a position adjustment member arranged above the fixed member and configured to position the base end of the support column and to adjust a position of a stage supported by the support column; and a plurality of gap height adjustment parts provided at respective ones of at least three positions surrounding a periphery of the support column in a circumferential direction, and configured to mount the position adjustment member to the fixed member in a state in which a gap height between the fixed member and the position adjustment member is adjustable, wherein at least one of the plurality of position adjustment mechanisms is provided with a fixedly mounting part, which is configured to mount the position adjustment member to the fixed member in a state in which the gap height is fixed, in place of the gap height adjustment parts at one of the at least three positions.

According to the present disclosure, it is possible to relatively easily adjust a position of a stage of a substrate processing apparatus.

### BRIEF DESCRIPTION OF DRAWINGS

FIG. 1 is a plan view for explaining a configuration of a substrate processing system according to an embodiment of the present disclosure.

FIG. 2 is a vertical cross-sectional side view of a substrate processing apparatus provided in the substrate processing system.

FIG. 3 is an exploded perspective view of the substrate processing apparatus.

FIG. 4 is a plan view illustrating a configuration of a lower end portion of a support column that supports a stage.

FIG. 5 is a first enlarged vertical cross-sectional side view of a position adjustment mechanism of the stage.

FIG. 6 is a second enlarged vertical cross-sectional side view of the position adjustment mechanism.

FIG. 7 is an enlarged plan view of the position adjustment mechanism.

FIG. 8 is a vertical cross-sectional side view relating to a centering process of the stage.

FIG. 9 is a plan view relating to the centering process of the stage.

FIG. 10 is a perspective view of a jig used for the centering process.

FIG. 11 is an image of a top surface of a stage imaged using a camera-equipped wafer.

### DETAILED DESCRIPTION

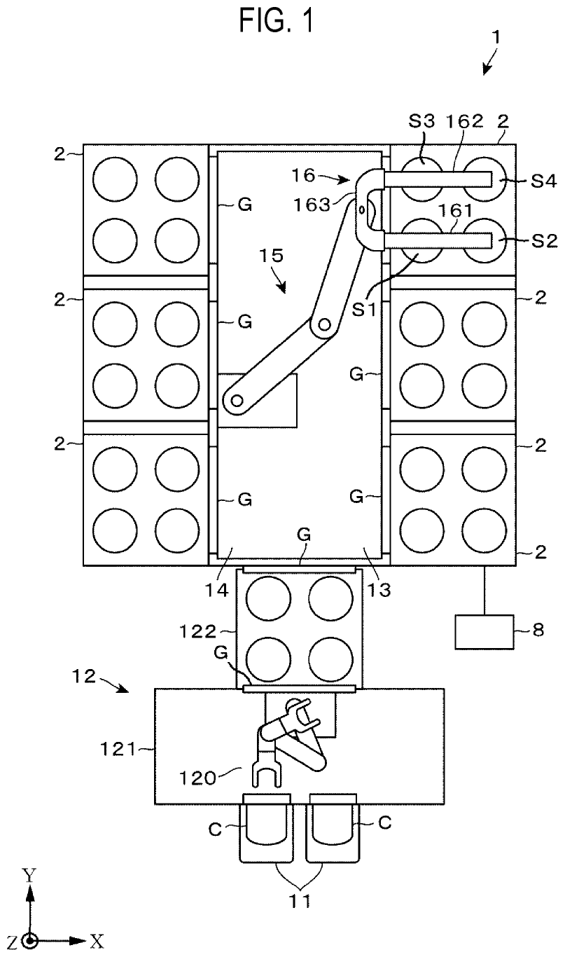

An embodiment of a substrate processing system 1 according to the present disclosure will be described with reference to a plan view of FIG. 1. The substrate processing system 1 includes loading/unloading ports 11, a loading/unloading module 12, a vacuum transfer module (a substrate transfer module) 13, and substrate processing apparatuses 2. In FIG. 1, an X direction will be referred to as a left-right direction, a Y direction will be referred to as a front-rear direction, and a side of the loading/unloading ports 11 will be referred to as a front side in the front-rear direction. The loading/unloading ports 11 and the vacuum transfer module 13 are connected to the loading/unloading module 12 on the front side and the rear side of the loading/unloading module 12, respectively, and face each other in the front-rear direction.

A carrier C which is a transfer container configured to accommodate a substrate to be processed is placed in each of the loading/unloading ports 11, and the substrate is formed of a wafer W which is a circular substrate having a diameter of, for example, 300 mm. The loading/unloading module 12 is a module configured to perform loading and unloading of the wafer W between the carrier C and the vacuum transfer module 13. The loading/unloading module 12 includes an atmospheric pressure transfer chamber 121 configured to deliver the wafer W to and from the carrier C under atmospheric atmosphere by a transfer mechanism 120, and a load-lock chamber 122 configured to switch an atmosphere under which the wafer W is placed between the atmospheric atmosphere and a vacuum atmosphere.

The vacuum transfer module 13 includes a vacuum transfer chamber (a substrate transfer chamber) 14 in which the vacuum atmosphere is formed, and a substrate transfer mechanism 15 is disposed inside the vacuum transfer chamber 14. The vacuum transfer chamber 14 has, for example, a rectangular shape having long sides in the front-rear direction in a plan view. Among four side walls of the vacuum transfer chamber 14, each of opposite long sides of the rectangle is connected to a plurality of (e.g., three) substrate processing apparatuses 2, and a short side on the front side is connected to the load-lock chamber 122 installed in the loading/unloading module 12. Reference symbol G in the drawings denotes gate valves interposed between the loading/unloading module 12 and the vacuum transfer module 13 and between the vacuum transfer module 13 and the substrate processing apparatuses 2. Each of the gate valves G opens and closes a loading/unloading port of the wafer W provided in modules connected to each other.

The substrate transfer mechanism 15 is configured to transfer the wafer W between the loading/unloading module 12 and each substrate processing apparatus 2 under the vacuum atmosphere and formed of an articulated arm, and includes a substrate holder 16 configured to hold the wafer W. As will be described later, the substrate processing apparatus 2 in this example performs a gas processing on a plurality of (e.g., four) wafers W in a batch under the vacuum atmosphere. Therefore, the substrate holder 16 of the substrate transfer mechanism 15 is configured to be capable of holding, for example, four wafers W so that the four wafers W are collectively delivered to the substrate processing apparatus 2.

The substrate holder 16 has a first substrate holder 161, a second substrate holder 162, and a connector 163. The first substrate holder 161 and the second substrate holder 162 are configured in a shape of two elongated spatulas extending horizontally and parallel to each other. The connector 163 extends horizontally so as to be orthogonal to an extending direction of the first and second substrate holders 161 and 162, and connects base ends of the first and second substrate holders 161 and 162 to each other. A central portion of the connector 163 in a length direction thereof is provided on a tip portion of the articulated arm, and the articulated arm turns around a vertical turning axis. Configurations of the first substrate holder 161 and the second substrate holder 162 will be described later.

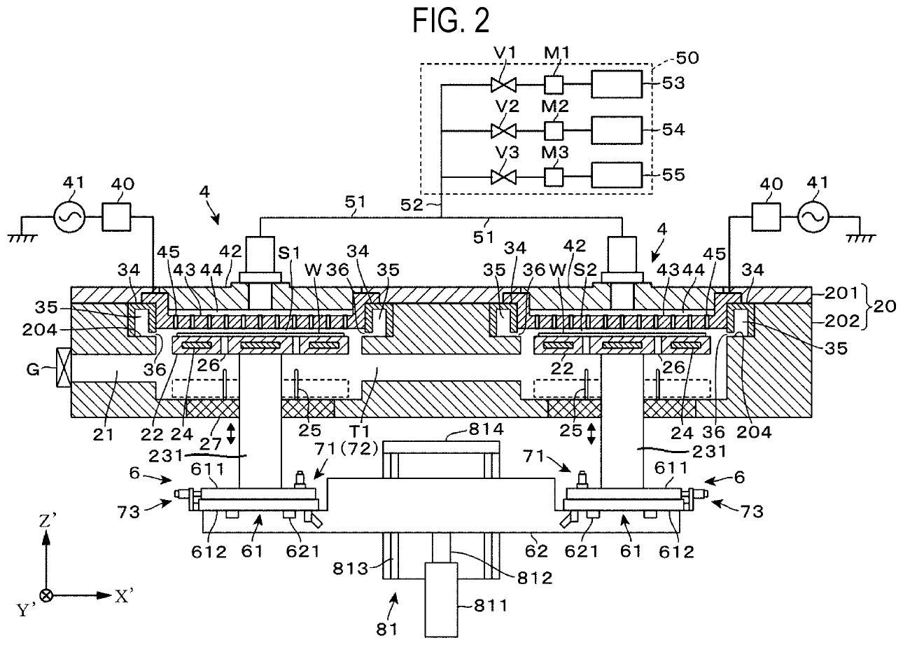

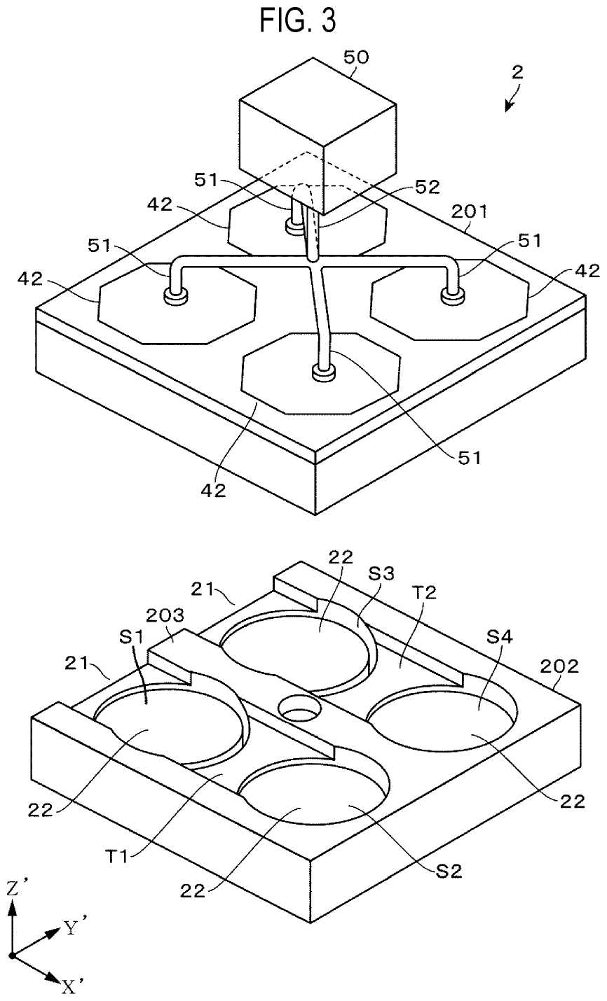

Subsequently, an example in which the substrate processing apparatus 2 is applied to a film forming apparatus that performs a plasma chemical vapor deposition (CVD) process, which is a type of film forming process, on wafers W will be described with reference to FIGS. 2 and 3. FIG. 2 is a vertical cross-sectional side view for explaining a configuration of the substrate processing apparatus 2, and FIG. 3 is an exploded perspective view of the same. FIGS. 2 to 4 also indicate sub-coordinates (X′-Y′-Z′ coordinates) for explaining arrangement relationships of devices in each substrate processing apparatus 2. With respect to the sub-coordinates, a connection position with the vacuum transfer module 13 will be referred to as a front side, an X′ in direction will be referred to as a front-rear direction, and a Y′ direction will be referred to as a left-right direction.

Six substrate processing apparatuses 2 are configured in the same manner as one another, and the substrate processing apparatuses 2 are capable of processing wafers W in parallel with one another. The substrate processing apparatus 2 includes a processing container 20 having a rectangular shape in a plan view. The processing container 20 is configured as a vacuum container capable of vacuum-evacuating an internal atmosphere thereof. Reference numeral 201 in FIGS. 2 and 3 indicates a ceiling of the processing container 20, and reference numeral 202 indicates a container body. In a side wall of the container body 202 on the front side, two loading/unloading ports 21 connected to the vacuum transfer chamber 14 via the gate valves G are formed so as to be arranged in the left-right direction (the Y′ direction in FIG. 3). The loading/unloading ports 21 are opened and closed by the gate valves G.

As illustrated in FIG. 3, inside the processing container 20, a first transfer space T1 and a second transfer space T2, which extend in the horizontal direction from respective loading/unloading ports 21 and via which the wafers W are transferred, are provided at positions adjacent to each other. In addition, an intermediate wall 203 is provided between the first and second transfer spaces T1 and T2 in the processing container 20 in an extending direction thereof (the X′ direction in FIG. 3). The horizontal direction referred to herein also includes a direction slightly tilted with respect to the extending direction within a range in which there is no risk of influence such as contact between devices during a loading/unloading operation of the wafers W due to influence of tolerance at the time of manufacturing.

In the first transfer space T1, two processing spaces S1 and S2 for performing a film forming process on the wafers W are arranged in a row along the extending direction of the first transfer space T1. Similarly, in the second transfer space T2, two processing spaces S3 and S4 are also arranged in a row along the extending direction of the second transfer space T2. Therefore, in the processing container 20, a total of four processing spaces S1 to S4 are arranged in a 2×2 matrix when viewed from a side of the top surface.

An internal structure of the processing container 20 including the processing spaces S1 to S4 will be described with reference to FIG. 2. The four processing spaces S1 to S4 are configured in the same manner as one another, and each of the processing spaces S1 to S4 is formed between a stage 22 on which a wafer W is placed and a gas supply 4 arranged so as to face the stage 22. FIG. 2 illustrates the processing spaces S1 and S2 of the first transfer space T1. Hereinafter, the processing space S1 will be described as an example.

The stage 22 also serving as a lower electrode is formed of, for example, metal or aluminum nitride (AlN) in which a metal mesh electrode is embedded, and has a flat disk shape. The stage 22 is supported by a support column 231 at the center position of the disk from a side of a bottom surface thereof. A lower portion of the support column 231 penetrates a bottom surface 27 of the processing container 20 and protrudes downwards. The support column 231 is capable of raising and lowering the stage 22 by an operation of a lifting mechanism 81 to be described later. In addition, a rotational driving mechanism may be provided at a base end portion of the support column 231, so that the stage 22 is configured to be rotatable around a vertical axis.

In FIG. 2, the stage 22 located at a processing position is drawn with a solid line, and the stage 22 located at a delivery position is drawn with a broken line. The processing position is a position when a substrate processing (a film forming process) which will be described later is performed, and the delivery position is a position when delivery of the wafer W is performed to and from the substrate transfer mechanism 15 described above. Reference numeral 24 in the drawing indicates a heater embedded in each stage 22, and the heater heats each wafer W placed on the stage 22 to 60 degrees C. to 600 degrees C. In addition, the stage 22 is grounded via a matcher (not illustrated).

In addition, on the bottom surface of the processing container 20, a plurality of (e.g., three) delivery pins 25 are provided at positions corresponding to the stage 22, and through holes 26 are formed in the stage 22 so as to form passage regions for the delivery pins 25. When the stage 22 is lowered to the delivery position, the delivery pins 25 pass through respective through holes 26, and upper ends of the delivery pins 25 protrude from a placement surface of the stage 22. Shapes of the first and second substrate holders 161 and 162 of the substrate transfer mechanism 15 and arrangement of the delivery pins 25 are set such that the delivery pins 25 and the first and second substrate holders 161 and 162 do not buffer one another when the wafer W is delivered between the delivery pins 25 and the first and second substrate holders 161 and 162.

Now, the first and second substrate holders 161 and 162 will described. The first substrate holder 161 is configured to hold wafers W at positions corresponding to respective arrangement positions of the processing spaces S1 and S2 in the first transfer space T1 when the first substrate holder 161 enters the first transfer space T1. The positions corresponding to respective arrangement positions of the processing spaces S1 and S2 in the first transfer space T1 are positions set to deliver wafers W to the two stages 22 provided in the processing spaces S1 and S2 of the first transfer space T1. In addition, the second substrate holder 162 is configured to hold wafers W at positions corresponding to respective arrangement positions of the processing spaces S3 and S4 in the second transfer space T2 when the second substrate holder 162 enters the second transfer space T2. The positions corresponding to respective arrangement positions of the processing spaces S3 and S4 in the second transfer space T2 are positions set to deliver wafers W to the two stages 22 provided in the processing spaces S3 and S4 of the second transfer space T2.

For example, a width of each of the first and second substrate holders 161 and 162 is smaller than a diameter of the wafers W, and rear surfaces of the wafers W are supported, at an interval from each other, on a side of a tip end and a side of the base end of each of the first and second substrate holders 161 and 162. In addition, the wafers W, which are supported on the side of the tip end and the side of the base end of the first and second substrate holders 161 and 162, respectively, have regions that do not overlap, for example, the first and second substrate holders 161 and 162. In addition, for example, center portions of the wafers W, which are supported on the side of the tip ends of the first and second substrate holders 161 and 162, are supported on the tip ends of the first and second substrate holders 161 and 162, respectively.

As described above, through the cooperation of the substrate transfer mechanism 15, the delivery pins 25, and the stage 22, four wafers W, for example, are collectively and concurrently delivered between the substrate transfer mechanism 15 and the stage 22 of each of the processing spaces S1 to S4. Reference numeral 27 in FIG. 2 indicates the bottom surface portion that includes a bearing configured to hold the support column 231 such that the support column 231 can move vertically while maintaining the interior of each processing container 20 to be airtight.

In addition, in the ceiling 201 of the processing container 20, a gas supply 4 serving as an upper electrode is provided above the stage 22 via a guide 34 formed of an insulating member. The gas supply 4 includes a lid 42, a shower plate 43 forming a facing surface provided to face the placement surface of the stage 22, and a gas flow chamber 44 formed between the lid 42 and the shower plate 43. A gas distribution path 51 is connected to the lid 42, and gas ejection holes 45 penetrating the shower plate 43 in a thickness direction thereof are arranged lengthwise and widthwise in the shower plate 43 such that a gas is ejected towards the stage 22 in a shower form.

The upstream side of the gas distribution path 51 connected to the gas supply 4 of each of the processing spaces S1 to S4 joins a common gas supply path 52 and is then connected to a gas supply system 50. The gas supply system 50 includes, for example, a reaction gas (a processing gas) source 53, a purge gas source 54, a cleaning gas source 55 for supplying a cleaning gas for removing a film deposited in the processing container 20, pipes, valves V1 to V3, flow controllers M1 to M3, and the like.

A radio frequency power supply 41 is connected to the shower plate 43 via a matcher 40. When radio frequency power is applied between the shower plate 43 (the upper electrode) and the stage 22 (the lower electrode), a gas supplied from the shower plate 43 to the processing space S1 (a reaction gas in this example) can be plasmarized through capacitive coupling.

In a vicinity of each of the processing spaces S1 to S4, the annular guide 34 is provided so as to form a slit exhaust port 36 opened in a slit shape along a circumferential direction of a corresponding one of the processing spaces S1 to S4. The guide 34 is inserted in a recess 204 formed in the container body 202, and form a flow path 35 through which a gas discharged from the corresponding one of the processing spaces S1 to S4 via the slit exhaust ports 36 passes. An exhaust port (not illustrated) is formed in each flow path 35, and the interior of the substrate processing apparatus 2 is vacuum-evacuated via an exhaust flow path (not illustrated) connected to the exhaust port.

Operation of performing a film forming process on wafers W by using the substrate processing system 1 having the above-described configuration will be briefly described.

When a carrier C accommodating wafers W to be processed is placed in the loading/unloading port 11, the wafers W are received by the transfer mechanism 120 of the loading/unloading module 12 under atmospheric atmosphere, and are transferred into the load-lock chamber 122. Subsequently, after switching the inside of the load-lock chamber 122 from the atmospheric atmosphere to a vacuum atmosphere, the wafers W in the load-lock chamber 122 are received by the substrate transfer mechanism 15 of the vacuum transfer module 13, and are transferred to a predetermined substrate processing apparatus 2 via the vacuum transfer chamber 14. As described above, the substrate transfer mechanism 15 enters the processing container 20 in the state in which two wafers W are held on each of the first substrate holder 161 and the second substrate holder 162 (i.e., in the state in which a total of four wafers W are held). Then, the stages 22 of the first and second transfer spaces T1 and T2 are raised and lowered to deliver the wafers W to the four stages 22 at the same time.

Subsequently, the first and second substrate holders 161 and 162 are retracted from the substrate processing apparatus 2, and the gate valves G are closed. Thereafter, respective stages 22 are raised to the processing position, and pressure adjustment in the processing container 20 and heating the wafers W by the heaters 24 are performed. Thereafter, in each of the processing spaces S1 to S4, a reaction gas for film formation is supplied from each gas supply 4, and a film forming process is performed by plasmarizing the reaction gas by turning on each radio frequency power supply 41.

At this time, the reaction gas is ejected in a shower form to the wafers W placed on the stages 22 of the respective processing spaces S1 to S4 via the shower plates 43. Thereafter, the reaction gas flows in a radial direction over surfaces of the wafers W, flows into the flow paths 35 via the slit exhaust ports 36, which are open in side peripheral portions of the processing spaces S1 to S4, and then is exhausted. At this time, since flows of the reaction gases, which are mutually matched in flow rate, flow direction, and plasma state, are formed in respective processing spaces S1 to S4, it is possible to form films, which are mutually matched in film thickness distribution and film quality, on the surfaces of the wafers W.

Then, when a predetermined time elapses and the film formation is completed, supplying the reaction gas and the radio frequency power and heating the wafers W are stopped, and the pressure in the processing container 20 is adjusted. Thereafter, the wafers W after the film forming process are simultaneously unloaded from the processing container 20 in an order reverse to that when the wafers W are loaded.

As described above, in order to dispose wafers W in different processing spaces S1 to S4 and to perform a film forming process for forming films having mutually matched film thickness distributions and film qualities, it is desirable that flows and plasmarized states of the reaction gas formed in respective processing spaces S1 to S4 are mutually matched. The flows and plasmarized states of the reaction gas formed in respective processing spaces S1 to S4 are affected by distances, degrees of parallelism, or the like between the bottom surfaces of the shower plates 43 and the top surfaces of the stages 22. In addition, when the centers of the guides 34 formed in an annular shape and the disk-shaped stages 22 are not aligned, distances from the outer peripheral end positions of the stages 22 to the slit exhaust ports 36 become uneven, which may cause deviation in the flows of the reaction gas.

For the reasons described above, each stage 22 needs to be accurately arranged at a predetermined position in the processing container 20. Therefore, when the substrate processing system 1 (the substrate processing apparatuses 2) is newly installed or when the substrate processing apparatuses 2 are reassembled after being disassembled for maintenance, adjusting the arrangement positions of the stages 22 are performed. Examples of items related to adjusting the arrangement positions may include adjusting inclinations of the support columns 231 and adjusting horizontal positions of the stages 22.

Conventionally, such position adjustments may take several hours on one stage 22. However, the substrate processing system 1 illustrated in FIG. 1, for example, includes six substrate processing apparatuses 2 in each of which four processing spaces S1 to S4 are arranged, and thus includes a total of twenty-four stages 22. Therefore, when it takes several hours to adjust a position of one stage 22, it may take a substantial amount of time to install and assemble one substrate processing system 1.

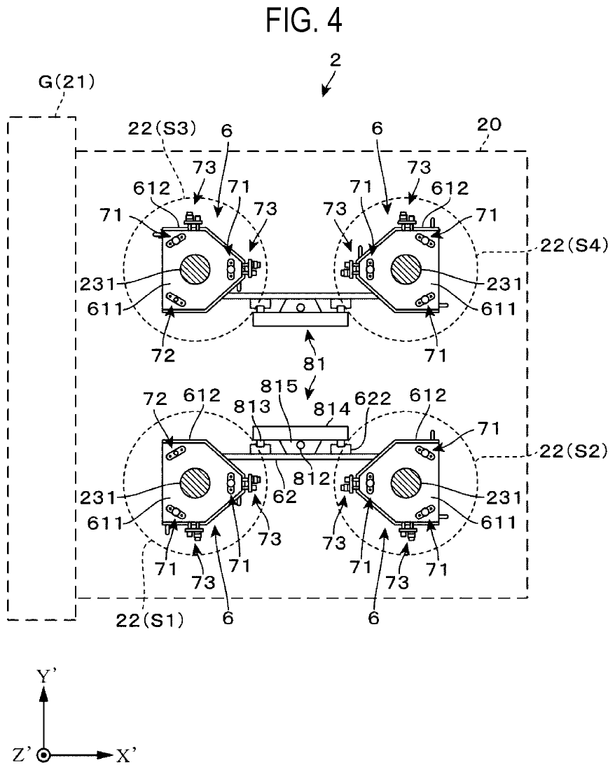

With respect to this point, the substrate processing apparatuses 2 of this example are provided with position adjustment mechanisms 6 configured to relatively easily adjust the positions of the plurality of stages 22. Hereinafter, a configuration of the position adjustment mechanism 6 will be described with reference to FIGS. 4 to 7 in addition to FIG. 2.

In the substrate processing apparatus 2 of this example, the two stages 22 arranged in the processing spaces S1 and S2 on the side of the first transfer space T1 and the two stages 22 arranged in the processing spaces S3 and S4 on the side of the second transfer space T2 are provided with position adjustment mechanisms 6 having a structure substantially common to each other. FIG. 2 shows an exemplary configuration of the position adjustment mechanisms 6 on the side of the processing spaces S1 and S2. However, for convenience of illustration, in FIG. 2, arrangement positions of gap height adjustment parts 71 and horizontal position adjustment parts 73, which will be described later, are changed, and illustration of fixedly mounting parts 72 is omitted (for exact arrangement positions, see FIG. 4).

As illustrated in FIG. 2, the lower end portion of each support column 231 protruding downwards from the bottom surface 27 of the processing container 20 is supported by a common base 62. In addition, the position adjustment mechanism 6 is provided between each support column 231 and the base 62.

The base 62 is a plate-shaped member laid horizontally along the first transfer space T1, and a support arm 621 configured to support the position adjustment mechanism 6 extends laterally from the base 62 towards a region below the stage 22. As illustrated in FIGS. 2 and 4, the base 62 is connected to the lifting mechanism 81 configured to simultaneously raise and lower both of the stages 22 of the processing spaces S1 and S2 between the processing position and the delivery position, which have been described above.

The lifting mechanism 81 includes an extendable rod 812 that is connected to a driving part 811 and extends and contracts in the vertical direction, and a guide plate 814 that is arranged in the direction of extension/contraction of the extendable rod 812. The base 62 is connected to the extendable rod 812 via a connecting body 815, and moves up and down as the extendable rod 812 extends and contracts. In addition, on the guide plate 814, two guide rails 813 extending in the direction of extension/contraction of the extendable rod 812 are arranged at positions on opposite sides of the extendable rod 812. Sliders 622 having recesses to which the guide rails 813 are fit are fixed to the base 62. Thus, it is possible to stably raise and lower the base 62 by moving the sliders 622 along the guide rails 813.

Next, a detailed configuration of the position adjustment mechanisms 6 will be described. Each position adjustment mechanism 6 includes a fixed plate (a fixed member) 612 fixedly disposed on the base 62, and a position adjustment plate (a position adjustment member) 611 disposed above the fixed plate 612 in a state of being fixed to the lower end portion of the support column 231. In addition, the position adjustment mechanism 6 is provided with the plurality of gap height adjustment parts 71 and the plurality of horizontal position adjustment parts 73 configured to adjust a relative positional relationship between the fixed plate 612 and the position adjustment plate 611. In addition, the fixedly mounting part 72 is provided at a predetermined position of one position adjustment mechanism 6.

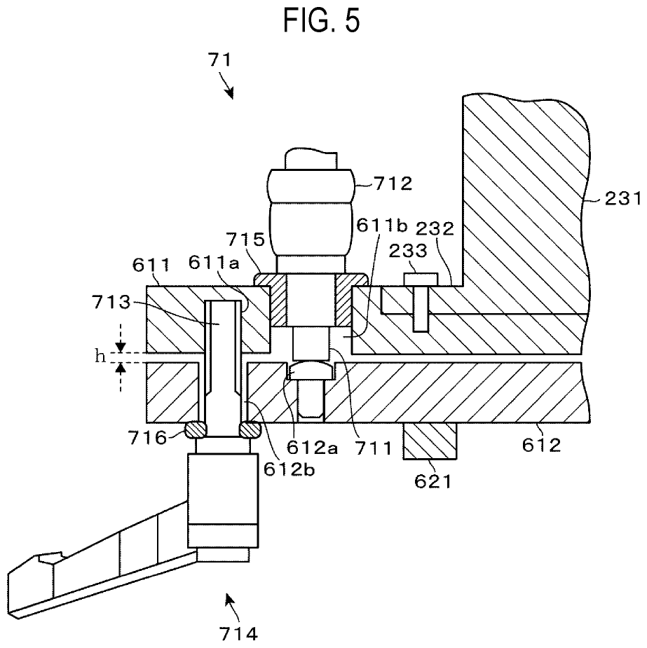

As illustrated in an enlarged vertical cross-sectional side view of FIG. 5, the fixed plate 612 is, for example, a plate-shaped member having a flat top surface, and is supported from a bottom surface thereof by the above-mentioned support arm 621 provided on the base 62. In addition, the position adjustment plate 611 is, for example, a plate-shaped member having a flat bottom surface, and the base end portion of the support column 231 is fixed to a top surface thereof to position the support column 231. FIG. 5 illustrates an example in which a flange 232 provided at the base end portion of the support column 231 is fixed to the position adjustment plate 611 via a fixing screw 233.

Here, in a case in which a rotational driving mechanism of the stage 22 is provided at the base end portion of the support column 231, a rotation shaft connected to a rotation motor or the like and having a diameter smaller than that of the support column 231 may protrude downwards from the lower end surface of the support column 231. The support column 231 may be positioned by providing openings for inserting the rotation shaft in the position adjustment plate 611 and the fixed plate 612, inserting the rotation shaft into these openings, and placing the lower end surface of the support column 231 on the top surface of the position adjustment plate 611.

FIG. 4 is a plan view illustrating a state in which the position adjustment mechanisms 6 are viewed downwards from a side of the bottom surface of the processing container 20. In FIG. 4, the arrangement positions of the processing container 20, the gate valve G, and each stage 22 are illustrated by broken lines. In this example, each of the position adjustment mechanisms 6 disposed correspondingly in the processing spaces S2 and S4 on the rear side when viewed from the gate valve G adjusts the inclination of the corresponding support column 231 by using three gap height adjustment parts 71. Meanwhile, each of the position adjustment mechanisms 6 disposed in the processing spaces S1 and S3 on the front side adjusts the inclination of the corresponding support column 231 by using two gap height adjustment parts 71 and one fixedly mounting part 72. In addition, each of the four position adjustment mechanisms 6 adjusts the position of the corresponding stage 22 in the horizontal direction by using two horizontal position adjustment parts 73.

For example, as illustrated in FIG. 5, each gap height adjustment part 71 has a pull screw 713 configured to fix the position adjustment plate 611 to the fixed plate 612, and a push screw 711 configured to regulate proximity of the position adjustment plate 611 and the fixed plate 612.

A male screw is formed at a tip end portion of the pull screw 713, which is screw-coupled with a female screw 611a provided so as to open toward a side of the bottom surface of the position adjustment plate 611. Meanwhile, a base end portion of the pull screw 713 penetrates a through-hole 612b provided in the fixed plate 612 and is connected to a clamp lever 714.

In addition, a gap is formed between a side peripheral surface of the pull screw 713 and the through-hole 612b so that the position adjustment plate 611 can be moved horizontally with respect to the fixed plate 612 by using the horizontal position adjustment parts 73.

A connection portion between the pull screw 713 and the clamp lever 714 is configured by a member having a diameter larger than an opening diameter of the through-hole 612b of the fixed plate 612. Therefore, the clamp lever 714 is configured as a support member for installing the position adjustment plate 611 above the fixed plate 612 by supporting the fixed plate 612 from the bottom surface thereof. In this example, a flat washer 716 is disposed between the bottom surface of the fixed plate 612 and the clamp lever 714 forming the support member.

In the configuration described above, it is possible to change a height h of the gap between the top surface of the fixed plate 612 and the bottom surface of the position adjustment plate 611 by rotating the pull screw 713 by using the clamp lever 714 to increase or decrease an amount of screw-coupling with the female screw 611a. The pull screw 713 and the clamp lever 714 form a pull screw part of the gap height adjustment part 71. In addition, it is not essential to support the fixed plate 612 by using the clamp lever 714, and for example, a nut screw-coupled with a male screw formed in a lower end region of the pull screw 713 may be used as the support member.

The push screw 711 serves to regulate proximity of the fixed plate 612 and the position adjustment plate 611 by bringing a head of a pin 612a inserted into the fixed plate 612 and a tip surface of the push screw 711 into contact with each other. Here, it is desirable that the head of the pin 612a, which is in contact with the tip surface of the screw 711, has a spherical shape. With this configuration, it is possible to maintain a height position that regulates the proximity of the fixed plate 612 and the position adjustment plate 611 constant even when a position where the push screw 711 comes into contact with the pin 612a is displaced in the horizontal direction.

A base end portion of a fixing member 715 penetrates a through-hole 611b provided in the position adjustment plate 611, and is connected to a micrometer head 712. The push screw 711 and the micrometer head 712 form a push screw part of the gap height adjustment part 71. The fixing member 715 for fixing the push screw part with respect to the position adjustment plate 611 is provided between the top surface of the position adjustment plate 611 and the micrometer head 712.

As illustrated in FIG. 4, each of the position adjustment mechanisms 6 disposed correspondingly to the processing spaces S2 and S4 on the rear side when viewed from the gate valve G is provided with the gap height adjustment parts 71 at three positions spaced apart from one another in the circumferential direction around the corresponding support column 231 and surrounding the support column 231. In this example, three gap height adjustment parts 71 are disposed at equal intervals in the circumferential direction around the support column 231. By adjusting the gap height h at these three positions, it is possible to freely adjust the inclination of the support column 231 positioned by the position adjustment plate 611 in the X′ direction and the Y′ direction in the drawing.

Meanwhile, each of the position adjustment mechanisms 6 disposed correspondingly to the processing spaces S1 and S3 on the front side when viewed from the gate valve G is provided with the above-mentioned gap height adjustment parts 71 at two positions spaced apart from each other in the circumferential direction around the corresponding support column 231 and surrounding the support column 231. In addition, the fixedly mounting part 72 is disposed at the remaining one position. In this example, these two gap height adjustment parts 71 and the one fixedly mounting part 72 are also disposed to be spaced apart from one another at an equal interval in the circumferential direction around the support column 231.

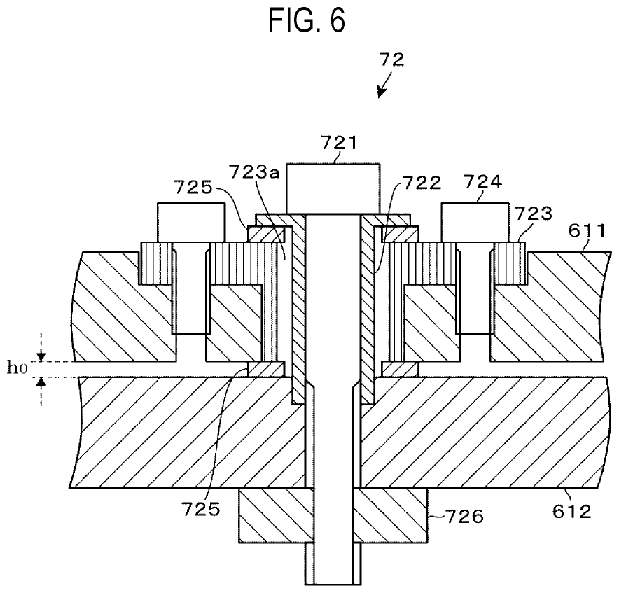

FIG. 6 is a vertical cross-sectional side view illustrating an exemplary configuration of the fixedly mounting part 72. The fixedly mounting part 72 includes a block 723, thrust washers 725, a collar 722, and a fixing bolt 721. The block 723 is provided so as to be closely fitted to the position adjustment plate 611 by using block bolts 724, and has a through-hole 723a formed therein in the vertical direction.

The thrust washers 725 are disposed on the upper side and the lower side of the block 723, and the collar 722 is disposed so as to penetrate the thrust washers 725 and the through-hole 723a in the block 723. A flange is formed at an upper end portion of the collar 722, and the flange is engaged with a top surface of the upper thrust washer 725. Meanwhile, in a state of being inserted into a through-hole opened in the top surface of the fixed plate 612, a lower end portion of the collar 722 is engaged with an upper end of a reduced-diameter portion formed in the through-hole. The fixing bolt 721 having a head is inserted into the collar 722 and the through-hole formed in the fixed plate 612. The fixed plate 612 is supported from the bottom surface thereof by screw-coupling a female screw of a nut 726 with a male screw formed at a lower end of the fixing bolt 721.

With the configuration described above, the collar 722, the upper thrust washer 725, the block 723, the lower thrust washer 725, and the fixed plate 612 are fastened to one another between the head of the fixing bolt 721 and the nut 726. In addition, by disposing the thrust washer 725 between the fixed plate 612 and the position adjustment plate 611, a gap having a height h₀ corresponding to a thickness of the thrust washer 725 is formed.

The fixedly mounting part 72 illustrated in FIG. 6 cannot change the height h₀ of the gap between the fixed plate 612 and the position adjustment plate 611 unless the thrush washer 725 is changed to another one having a different thickness. In other words, in the fixedly mounting part 72, the gap height is fixed to h₀.

In addition, a gap is formed between a side peripheral surface of the collar 722 and the through-hole 723a in the block 723 so that the position adjustment plate 611 can be moved horizontally with respect to the fixed plate 612 by using the horizontal position adjustment parts 73.

As illustrated in FIG. 4, in the substrate processing apparatus 2 of this example, the plurality of stages 22 are disposed side by side in rows along a direction of entrance of the first and second substrate holders 161 and 162 (the extending direction of the first and second transfer spaces T1 and T2). In addition, of the stages 22 of each set, the fixedly mounting part 72 is provided for the position adjustment mechanism 6 of the support column 231 that supports the stage 22 disposed closest to the loading/unloading port 21.

In addition, as illustrated in FIG. 4, the fixedly mounting part 72 is provided at the position closest to the loading/unloading port 21 among the three positions spaced apart from one another in the circumferential direction around the corresponding support column 231 and surrounding the support column 231. In the example illustrated in FIG. 4, one gap height adjustment part 71 and one fixedly mounting part 72 are disposed at positions substantially equidistant from the loading/unloading port 21 in each of the two position adjustment mechanisms 6 disposed at positions close to the loading/unloading port 21 in a plan view. In this case, the fixedly mounting parts 72 may be disposed at positions that are difficult to access from the side surfaces of the substrate processing apparatus 2, that is, at positions far from opposite side walls of the processing container 20 when viewed from the loading/unloading port 21.

In the position adjustment mechanism 6 described above, two gap height adjustment parts 71 and one fixedly mounting part 72 are disposed at an equal interval in the circumferential direction around the support column 231. Even when the gap height is fixed to h₀ by the fixedly mounting part 72 at one position, it is possible to adjust the gap height h by the gap height adjustment parts 71 at the remaining two positions. As a result, it is possible to freely adjust the inclination of the support column 231 positioned by the position adjustment plate 611 in the X′ direction and the Y′ direction in FIG. 4.

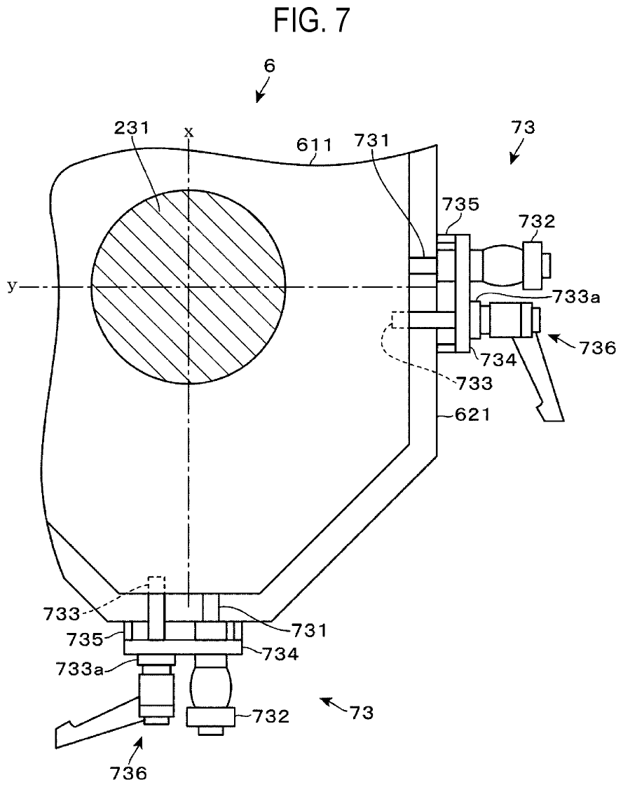

Next, an exemplary configuration of the horizontal position adjustment parts 73 configured to adjust the horizontal positions of respective stages 22 will be described. For example, as illustrated in FIGS. 2 and 7, the horizontal position adjustment parts 73 are provided on a side surface of the fixed plate 612. As illustrated in FIG. 7, in a plan view of the position adjustment mechanism 6, the horizontal position adjustment parts 73 are disposed at positions at which straight lines drawn from the center of the support column 231 towards two intersecting directions (orthogonal directions in this example) (the x-axis and y-axis indicated by one-dot chain lines in FIG. 7) intersect with the side surfaces of the position adjustment plate 611 and the fixed plate 612, respectively. At the positions at which the horizontal position adjustment parts 73 are disposed, the fixed plate 612 and the position adjustment plate 611 are configured such that the side surface of the position adjustment plate 611 disposed on the upper side is located inward of the side surface of the fixed plate 612 disposed on the lower side.

Holding members 734 are disposed at positions facing the side surface of the position adjustment plate 611. The holding members 734 are small plate-shaped members disposed such that plate surfaces thereof face the side surface of the position adjustment plate 611, and are fixed to the side surface of the fixed plate 612 by fixing members 735. The holding members 734 and the fixing members 735 correspond to a holding part of this example.

The holding member 734 holds a pull screw 733 that mounts the position adjustment plate 611 with respect to the holding member 734 in a state in which the position of the position adjustment plate 611 can be moved horizontally. In addition, the holding member 734 holds a push screw 731 that regulates proximity of the holding member 734 to the side surface of the position adjustment plate 611.

A male screw is formed at a tip end portion of the pull screw 733, and is screw-coupled with a female screw provided so as to open towards the side surface of the position adjustment plate 611. In addition, a base end portion of the pull screw 733 penetrates the holding member 734 and is fixed to the holding member 734 via a flat washer 733a by a clamp lever 736 provided at the penetrating position. The position adjustment plate 611 can be moved horizontally by increasing or decreasing an amount of screw-coupling between the female screw in the position adjustment plate 611 and the pull screw 733 by using the clamp lever 736. The pull screw 733 and the clamp lever 736 form a pull screw part of the horizontal position adjustment part 73.

The push screw 731 regulates proximity of the position adjustment plate 611 and the holding member 734 by bringing a tip surface thereof into contact with the side surface of the position adjustment plate 611, and positions the position adjustment plate 611 in the horizontal direction. A base end portion of the push screw 731 penetrates the holding member 734 and is connected to a micrometer head 732. The push screw 731 and the micrometer head 732 form a push screw part of the horizontal position adjustment part 73.

An exemplary method of adjusting the position of each stage 22 by using the position adjustment mechanisms 6 having the configuration described above will be described. It is assumed that when installing the substrate processing apparatus 2, each stage 22 is installed on the lifting mechanism 81 via the position adjustment mechanism 6 and is transferred in a temporarily positioned state. The position adjustment of the substrate processing apparatus 2 is started from the stages 22 connected to the position adjustment mechanisms 6 provided with the fixedly mounting parts 72. In the example illustrated in FIG. 4, the position adjustment is started from the stages 22, which are arranged on the side of the loading/unloading port 21 and use the position adjustment mechanisms 6 including the fixedly mounting parts 72. Hereinafter, position adjustment of the stages 22 arranged in the processing spaces S1 and S2 on the side of the first transfer space T1 will be described as an example.

First, the ceiling 201 of the processing container 20 is opened, and a total of six capacitance sensors (not illustrated) (three capacitance sensors for each stage 22) are disposed so as to be located above the gap height adjustment parts 71 and the fixedly mounting part 72 provided in two position adjustment mechanisms 6. Thereafter, when the ceiling 201 is closed, the top surfaces of the stages 22 and the bottom surfaces of the shower plates 43 come to be in a state of facing each other, and each of the capacitance sensors may output a signal corresponding to a distance to the bottom surface of corresponding one of the shower plates 43.

As described above with reference to FIG. 6, since the position adjustment mechanism 6 on the side of the processing space S1 is provided with the fixedly mounting part 72, at this position, the gap height between the top surface of the fixed plate 612 and the bottom surface of the position adjustment plate 611 is fixed to h₀ in advance. Therefore, based on an output of the capacitance sensor disposed above the fixedly mounting part 72, the stage 22 is raised to the position at which a height dimension between the top surface of the stage 22 and the bottom surface of the shower plate 43 becomes a preset value.

At this time, when the support column 231 is tilted, the height dimension is not constant between the entire facing surfaces of the stage 22 and the shower plate 43. Thus, the gap height h at each position is adjusted by using the horizontal position adjustment parts 73 provided at the remaining two positions. That is, based on an output of the capacitance sensor disposed above each horizontal position adjustment part 73, adjustment to decrease the gap height h on the side of the position adjustment mechanism 6 is performed when the height dimension is small, and adjustment to increase the gap height h on the side of the position adjustment mechanism 6 is performed when the height dimension is large.

Referring to FIG. 5, when increasing the gap height h, the pull screw 713 is turned by the clamp lever 714 to separate the fixed plate 612 from the position adjustment plate 611 with a certain margin. Thereafter, the tip surface of the push screw 711 is lowered by a predetermined amount by using the micrometer head 712, and then the clamp lever 714 is turned in the opposite direction so as to raise the fixed plate 612 to a position at which the head of the pin 612a comes into contact with the tip surface of the push screw 711. On the other hand, when decreasing the gap height h, the tip surface of the push screw 711 is raised by a predetermined amount by using the micrometer head 712, and then the clamp lever 714 is turned so as to raise the fixed plate 612 to a position at which the head of the pin 612a comes into contact with the tip surface of the push screw 711.

Since the proximity of the fixed plate 612 and the position adjustment plate 611 is regulated by using the micrometer head 712, it is possible to adjust the gap height h with high precision. In addition, since the pull screw 713 that is operated from the side of the bottom surface of the fixed plate 612d is provided with the clamp lever 714, it is easy to operate.

As described above, when the height dimensions at locations above the gap height adjustment parts 71 provided at the two positions become the preset value, the height dimension becomes constant between the entire facing surfaces of the stage 22 and the shower plate 43. When the height dimension on the side of the fixedly mounting part 72 is changed by adjusting the inclination of the support column 231, fine adjustment is performed, for example, to slightly raise or lower the stage 22 by the lifting mechanism 81.

Thereafter, the position of the stage 22 on the side of the processing space S2 is adjusted.

Since the stages 22 disposed on the side of the two processing spaces S1 and S2 are supported by the common base 62, the two stages 22 move up and down in synchronization with each other. Therefore, as illustrated in FIG. 2, when heights of the support columns 231 supporting the respective stages 22 are configured to be the same as each other and thicknesses of the stages 22 themselves are configured to be the same as each other, the top surfaces of both stages 22 are located at substantially the same height.

Therefore, the height dimension between the stage 22 and the shower plate 43 on the side of the processing space S2 is adjusted based on the height dimension at a location above the fixedly mounting part 72 on the side of the processing space S1. That is, the gap height h of each gap height adjustment part 71 is adjusted such that the height dimension becomes the preset value based on an output of the capacitance sensor located above each of the gap height adjustment parts 71 provided at three positions of the position adjustment mechanism 6 on the side of the processing space S2.

With the method described above, it is possible to make the height dimensions between the facing surfaces of the stages 22 and the shower plates 43 uniform by adjusting the inclinations of the support columns 231 supporting the stages 22 arranged in a row along the first transfer space T1. When the position adjustment is completed, the ceiling 201 is opened and the capacitance sensors on the stages 22 are removed.

Next, an exemplary horizontal position adjustment method using the horizontal position adjustment parts 73 will be described. First, the ceiling 201 is opened in a state in which the stage 22 is raised to the processing position, and a distribution of a width dimension of an annular gap between the side peripheral surface of the stage 22 and the guide 34 (the slit exhaust port 36) is measured by using a caliper or the like. From this measurement result, an amount of deviation between the center of the stage 22 and the center of the guide 34 is obtained, and an amount of movement of the position adjustment plate 611 in each of the x-axis and y-axis directions of FIG. 7 is specified so as to eliminate the amount of deviation.

Referring to FIG. 7, when moving the position adjustment plate 611 in a direction away from the holding members 734, the side surfaces of the position adjustment plate 611 are spaced apart from the holding members 734 with a certain margin by turning the pull screws 733 using the clamp levers 736. Then, after causing the tip surfaces of the push screws 731 to protrude by a predetermined amount using the micrometer heads 732, the clamp levers 736 are turned in the opposite direction so as to move the position adjustment plate 611 to a position at which the side surfaces thereof are brought into contact with the tip surfaces of the push screws 731 by the pull screws 733. On the other hand, when the position adjustment plate 611 is moved in a direction approaching the holding members 734, the tip surfaces of the push screws 731 are retracted by a predetermined amount using the micrometer heads 732. Thereafter, the pull screws 733 are turned using the clamp levers 736 to move the position adjustment plate 611 to a position at which the side surfaces thereof are in contact with the tip surfaces of the pull screws 733.

Since the proximity of the position adjustment plate 611 and the holding members 734 is regulated by using the micrometer heads 732, it is possible to adjust the horizontal position of the position adjustment plate 611 with precision.

Here, as described above with reference to FIGS. 5 and 6, gaps are formed around the pull screw 713 penetrating the through-hole 612b in the fixed plate 612 and around the collar 722 penetrating the through-hole 723a in the block 723. In addition, thrust washers 725 are provided on the upper side and the lower side of the block 723, respectively, which is provided integral with the position adjustment plate 611. With these configurations, the position adjustment plate 611 can move horizontally relative to the fixed plate 612 by the operation of the fixedly mounting part 72 described above.

In addition, in each horizontal position adjustment part 73, a gap (not illustrated) is formed at a position at which the pull screw 733 penetrates the holding member 734. With this configuration, when the position adjustment plate 611 is moved horizontally by using one horizontal position adjustment part 73, the holding member 734 in the other horizontal position adjustment part 73 can move relative to the pull screw 733.

By adjusting the position of the stage 22 on the side of the second transfer space T2 by the method described above, the position adjustment of all the stages 22 in the substrate processing apparatus 2 is completed without using a tool. In addition, the position adjustment of the four stages 22 in the first and second transfer spaces T1 and T2 may be performed in an order of sequentially performing the inclination adjustment of the support columns 231 and then performing the horizontal position adjustment.

When the position adjustment is completed, the ceiling 201 of the processing container 20 is installed, each substrate processing apparatus 2 is connected to the vacuum transfer module 13, and connection of various pipes or the like is performed, thereby configuring the substrate processing system 1.

With the substrate processing apparatus 2 of the present disclosure, by using the position adjustment mechanisms 6, it is possible to relatively easily adjust the positions of the stages 22 without using a tool. In particular, in one of the two stages 22 supported by the common base 62, the gap height between the fixed plate 612 and the position adjustment plate 611 is set to h₀ by the fixedly mounting part 72. Therefore, it is possible to relatively simply adjust the positions of the stages 22 supported by the common base 62 by using the position where the fixedly mounting part 72 is provided as a reference.

As a comparison with the present disclosure, consider a case where gap height adjustment parts 71 are provided at all positions of the two position adjustment mechanisms 6 on the side of the processing spaces S1 and S2 (the first transfer space T1) of FIG. 4. In this case, the height dimensions between the stages 22 and the shower plates 43 are determined by two factors, i.e., an arrangement height of the base 62, which is raised and lowered by the lifting mechanism 81, and the gap height h.

Therefore, when setting the height dimension to a predetermined value, a plurality of combination cases of the arrangement height of the base 62 and the gap height h occur, which makes it difficult to determine which combination case should be selected. As a result, it may take time to adjust the inclination of each support column 231.

In addition, a comparative technique in which one fixedly mounting part 72 is provided for each of two position adjustment mechanisms 6 on the sides of the processing spaces S1 and S2 of FIG. 4 is also reviewed. For example, height dimensions above the respective fixedly mounting parts 72 may be different from each other due to tolerances in manufacturing constituent members such as the position adjustment plates 611, the support columns 231, the stages 22, and the like, or occurrence of distortion of the members. In such a case, when the fixedly mounting parts 72 are provided on both position adjustment mechanisms 6, in order to make the height dimensions at both positions uniform, it becomes necessary to procure thrust washers 725 having different thicknesses and to disassemble the position adjustment mechanisms 6 to replace the thrust washers 725.

Compared with each of the above-mentioned comparative techniques, in the substrate processing apparatus 2 of the present disclosure, it is possible to perform position adjustment precisely with a simple operation while maintaining flexibility of the position adjustment of the stages 22. When the range of interest is expanded from the two position adjustment mechanisms 6 supported by the common base 62 and the entire substrate processing apparatus 2 is viewed, the substrate processing apparatus 2 is provided with four position adjustment mechanisms 6. In addition, the fixedly mounting part 72 is provided in each of two position adjustment mechanisms 6, among the four position adjustment mechanisms 6 (see FIG. 4).

In addition, in the present disclosure, the fixedly mounting parts 72, which do not perform an operation of position adjustment, are provided in the position adjustment mechanisms 6 configured to perform position adjustment of the stages 22 disposed closest to the side of the loading/unloading port 21. Further, each fixedly mounting part 72 is provided at the position closest to the loading/unloading port 21 among the three installation positions spaced apart from one another in the circumferential direction around the corresponding support column 231 and surrounding the support column 231.

At this time, as illustrated in FIG. 1, for example, suppose that it is necessary to perform maintenance for performing position adjustment using the position adjustment mechanisms 6 in a state in which a plurality of substrate processing apparatuses 2 is connected to the vacuum transfer module 13. Even in such a case, the fixedly mounting parts 72 are disposed at positions that are most difficult to access from outside of the side walls of the processing container 20. Therefore, it is possible to dispose the gap height adjustment parts 71, which may perform adjustment of the gap height h, at positions that are easier to access.

Further, as in the example illustrated in FIG. 4, when two rows in which a plurality of stages 22 is arranged are provided, the fixedly mounting parts 72 may be disposed respectively at positions at which the rows are adjacent to each other (a center side when viewed from the loading/unloading port 21). Even in this case, it is possible to dispose the gap height adjustment parts 71 at positions that are close to the opposite side walls when viewed from the loading/unloading port 21 and are easy to access from outside.

Variations of the above-described embodiment will be described. The fixed members and the position adjustment members are not limited to those formed by plates. For example, elongated rod-shaped plate members may be provided so as to extend radially from a disk supporting the support column 231 towards the respective arrangement positions of the gap height adjustment parts 71, the fixedly mounting parts 72, and the horizontal position adjustment parts 73.

The number of stages 22 supported by the common base 62 and subjected to position adjustment by the position adjustment mechanisms 6 is not limited to the example in which the number is two, and may be three or more. In addition, in consideration of correcting distortion of the stages 22 or the like, the gap height adjustment parts 71 may be provided at four or more positions that are separated from one another in the circumferential direction around each support column 231 (even in this case, one fixedly mounting part 72 is provided at one of the positions in one position adjustment mechanism 6). In addition, when the necessity for disposing the gap height adjustment parts 71 at positions that are easy to access is small, the arrangement positions of the fixedly mounting parts 72 may be freely set.

In addition, when a plurality of position adjustment mechanisms 6 is provided on the common base 62, it cannot be said that it is an essential requirement to provide the fixedly mounting part 72 only on one position adjustment mechanism 6. For example, when a member or the like that is less likely to cause distortion is used and a difference in height dimension of a plurality of fixedly mounting parts 72 provided on the common base 62 is within an allowable range, the fixedly mounting part 72 may be provided on each of position adjustment mechanisms 6.

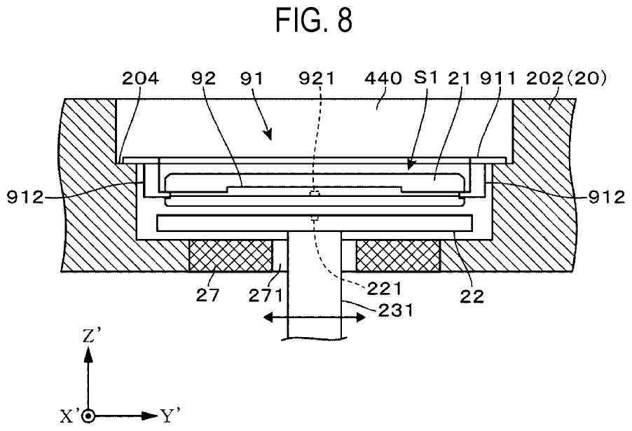

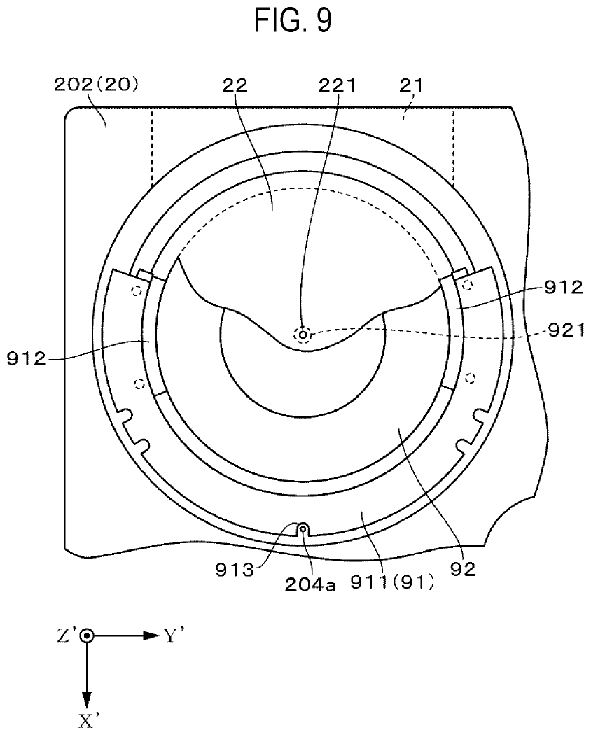

Next, an exemplary method of performing position alignment of a stage 22 by using the above-mentioned position adjustment mechanism 6, for example, when installing the stage 22 in a substrate processing apparatus 2 will be described with reference to FIGS. 8 to 11. FIGS. 8 and 9 illustrate an example in which the stage 22 arranged in the processing space S1 described with reference to FIGS. 1 and 2 is selected as a target stage of the position alignment.

In this example, a method of performing a centering process of disposing a central portion of the stage 22 at a correct position in the processing space S1 by using the above-described horizontal position adjustment parts 73 will be described. With respect to other processing spaces S2 to S4, the centering process may be performed by the same method as in the example described below.

FIG. 8 is an enlarged vertical cross-sectional side view of a region around the processing space S1 in the substrate processing apparatus 2 illustrated in FIG. 2, and FIG. 9 is a plan view of the region.

The example illustrated in FIGS. 8 and 9 is in a state before the ceiling 201, the shower plates 43, and the guides 34 for forming the flow paths 35, which have been described with reference to FIG. 2, are installed, and the position alignment is performed in a state in which the opening 440 above the processing space S1 is opened.

As illustrated in FIGS. 8 and 9, in the central portion on the top surface of the stage 22 inserted into the processing container 20 (the container body 202), a target groove 221 as a mark for specifying a position for centering is formed towards the processing space S1. In the example described below, the stage 22 is centered based on a result of imaging the target groove 221. A camera-equipped wafer (a camera-equipped substrate) 92 capable of being transferred by using the substrate holder 161 provided in the substrate transfer mechanism 15 described above is used as an imaging part configured to capture an image of the target groove 221. In addition, similar to the example of transferring wafers W described with reference to FIG. 1 and the like, a camera-equipped wafer 92 may be transferred with respect to the processing space S2 by using the substrate holder 161, and camera-equipped wafers 92 may be transferred with respect to the processing spaces S3 and S4 by using the substrate holder 162.

The camera-equipped wafer 92 has a structure in which a camera 921 is provided at a center portion of a disk-shaped member having the same size as the wafer W, and a commercially available product may be used. For example, the camera-equipped wafer 92 outputs a captured image to an image processor via wireless communication or the like, and the result is displayed on a monitor. In addition, by holding the camera-equipped wafer 92 at a position above the stage 22 in a state in which the camera 921 faces a side of a bottom surface thereof, it is possible to image the target groove 221 formed on the top surface side of the stage 22.

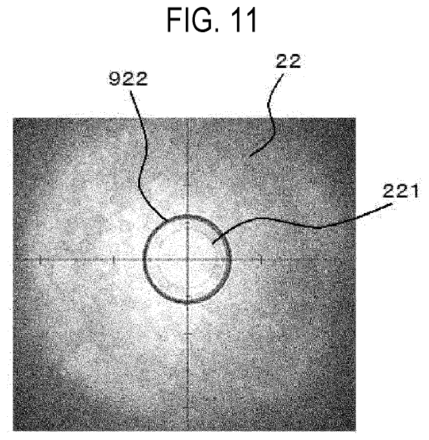

Here, as illustrated in FIG. 11, a sight 922, which serves as a target position for aligning an arrangement position of the target groove 221, is set within an imaging range of the camera-equipped wafer 92. Therefore, when the camera-equipped wafer 92 is held at a preset position and the position of the target groove 221 is aligned with the sight 922, it is possible to perform the centering process of the stage 22. In this example, a holding jig 91 is used as a method of holding the camera-equipped wafer 92 at the preset position as described above.

As illustrated in FIGS. 8 and 9, the holding jig 91 configured to hold the camera-equipped wafer 92 at the preset position for centering the stage 22 is disposed in the processing container 20 (the container body 202).

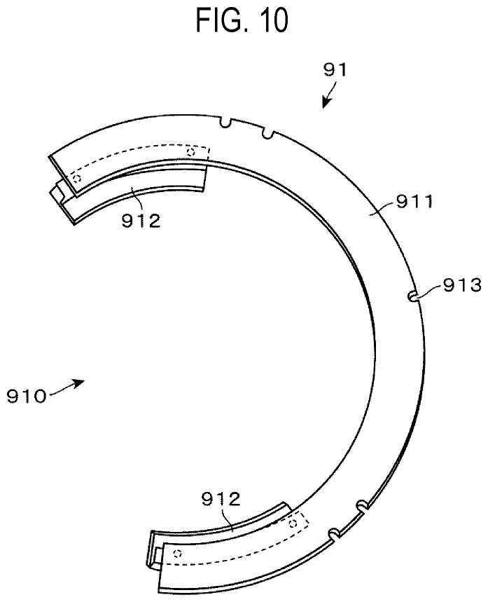

As illustrated in an external perspective view of FIG. 10, the holding jig 91 has a body portion 911 formed of a semiring-shaped member, and a plurality of wafer pockets 912 provided so as to protrude inward in an L shape from an inner peripheral portion on a side of a bottom surface of the body portion 911 when viewed from a side and configured to hold a peripheral edge portion of the camera-equipped wafer 92 from the bottom surface thereof.

As illustrated in FIGS. 8 and 9, for example, the holding jig 91 is installed in an upper peripheral region of the processing space S1 such that each wafer pocket 912 is in a state of being inserted toward the inside of the processing space S1. In this example, the body portion 911 of the holding jig 91 is supported from the side of the bottom surface by the bottom surface of the above-described recess 204 formed in the container body 202, before the guide 34 is disposed therein. As illustrated in FIG. 9, at this time, the holding jig 91 is positioned by installing the holding jig 91 such that a position alignment protrusion 204a provided at a predetermined position of the recess 204 is inserted into a notch 913 formed at a predetermined position of the body portion 911 (a process of installing the holding jig 91).

In addition, the camera-equipped wafer 92 is transferred such that the camera 921 is disposed at a preset position for performing the centering process, by using the substrate transfer mechanism 15 to which the transfer position has been taught in advance. Thereafter, the camera-equipped wafer 92 is delivered to the holding jig 91, and peripheral portions of the camera-equipped wafer 92 are supported from sides of the bottom surfaces thereof by the wafer pockets 912, whereby the camera-equipped wafer 92 is held at the preset position.

At this time, as illustrated in FIG. 10, a cutout portion 910 is formed in the semiring-shaped body portion 911 at a region corresponding to a movement path of the substrate holder 161 holding the camera-equipped wafer 92. With this configuration, it is possible to deliver the camera-equipped wafer 92 while avoiding interference between the substrate holder 161 and the holding jig 91 (a process of causing the holding jig 91 to hold the camera-equipped wafer 92).

Subsequently, after the substrate holder 161 is retracted from the processing space S1, the top surface of the stage 22 is imaged by the camera 921 (a process of imaging the target groove 221). The camera-equipped wafer 92 is held at the preset position by the holding jig 91, and the support column 231 that supports the stage 22 is also approximately positioned because the support column 231 is inserted into an opening 271 formed in the bottom surface 27 of the container body 202. As a result, the target groove 221 formed in the top surface of the stage 22 is located within a usual imaging range of the camera 921.

In addition, in order to prevent external air from entering the processing spaces S1 to S4 via the openings 271 formed in the bottom surfaces 27, a bellows (not illustrated) is provided in a vicinity of each support column 231 to airtightly cover a space in the vicinity of the support column 231 including the opening 271.

In addition, as illustrated in FIG. 11, the centering process is performed by using the horizontal position adjustment parts 73 of the above-described position adjustment mechanism 6 provided on the stage 22 such that the target groove 221 displayed in the captured image is aligned with the sight 922 set in the imaging range (a process of aligning the stage 22 in the horizontal direction).

When the centering process of the stage 22 with respect to the processing space S1 is completed as described above, the installation position of the holding jig 91 is sequentially changed to the remaining processing spaces S3 to S4, and centering processes of the remaining stages 22 are performed in the same procedure as the above example.

According to the method described above, compared with, for example, a case where the centering process is performed by disposing a jig for position adjustment between the outer peripheral side surface of the stage 22 and the inner peripheral side surface of the container body 202 forming the processing space S1, there is no risk of misalignment when removing the jig for position adjustment. In addition, since the centering process is performed by using a captured image obtained by the camera 921, it is possible to numerically manage accuracy of alignment and the like based on the number of pixels or the like.

The configuration of the imaging part configured to image the target groove 221 is not limited to the case in which the camera-equipped wafer 92 illustrated in FIGS. 8 and 9 is used. The stage 22 may be centered by using a holding jig 91 capable of holding a charge-coupled device (CCD) camera at a preset position.

In addition, with respect to the method of centering the stage 22, the centering process may be performed using a method different from the method in which the camera-equipped wafer 92 is held at the preset position of the holding jig 91, by using a substrate transfer mechanism 15 to which the method of centering the stage 22 described above has been taught in advance. For example, a configuration, in which a guide groove or the like is provided on the wafer pockets 912 of the holding jig 91 and the camera-equipped wafer 92 is guided toward the preset position and held, may be adopted.

In addition, at this time, a result of centering the stage 22 may be used to correct the teaching of the substrate transfer mechanism 15.

As a method of correcting the teaching, for example, the camera-equipped wafer 92 after centering the stage 22 is unloaded to the load-lock chamber 122, and a stage of a wafer W provided in the load-lock chamber 122 is imaged. Similar to the stage 22 on the side of the processing container 20, a mark for identifying a position is also formed on the stage on the side of the load-lock chamber 122, and the mark is imaged by the camera-equipped wafer 92.

Thereafter, a result of imaging the target groove 221 in the stage 22 on the side of the processing container 20 for which the centering process has been performed is compared with a result of imaging the mark on the side of the load-lock chamber 122. Based on this comparison result, it is possible to correct positions to be taught to a control mechanism of the substrate transfer mechanism 15 such that the substrate transfer mechanism 15 accurately transfers a wafer W between a preset position on the stage in the load-lock chamber 122 and a preset position on a stage 22 on the side of the processing container 20.

The vacuum process performed by the substrate processing apparatus 2 according to each of the above-described embodiments is not limited to a film form process through a CVD method, but may be a film forming process through an atomic layer deposition (ALD) method or an etching process. The film forming process through an ALD method is a film forming process of depositing a reaction product by repeating multiple times a process of adsorbing a raw material gas onto a wafer W and a process of reacting the raw material gas adsorbed on the wafer W with a reaction gas to produce the reaction product. In addition, in the substrate processing system 1, the number of substrate processing apparatuses 2 connected to the vacuum transfer chamber 14 may be one.

It should be understood that the embodiments disclosed herein are illustrative and are not limiting in all aspects. The embodiments described above may be omitted, replaced, or modified in various forms without departing from the scope and spirit of the appended claims.

### EXPLANATION OF REFERENCE NUMERALS

W: wafer, 2: substrate processing apparatus, 20: processing container, 22: stage, 231: support column, 6: position adjustment mechanism, 611: position adjustment plate, 612: fixed plate, 62: base, 71: gap height adjustment part, 72: fixedly mounting part

What is claimed is:

1. A substrate processing apparatus for processing a substrate by supplying a processing gas to the substrate, the apparatus comprising:
a plurality of stages which is disposed in a processing container and on each of which a substrate to be processed is placed;
a plurality of support columns configured to support the plurality of stages from bottom surfaces of the stages, respectively, and penetrating a bottom surface of the processing container so as to protrude downward from the bottom surface of the processing container;
a common base configured to support the plurality of support columns from base ends of the support columns; and
a plurality of position adjustment mechanisms, each of which includes:
a fixed member provided between the base and the base end of each of the support column and fixed to the base;
a position adjustment member arranged above the fixed member, and configured to position the base end of the support column and to adjust a position of a stage supported by the support column; and
a plurality of gap height adjustment parts provided at respective ones of at least three positions surrounding a periphery of the support column in a circumferential direction, and configured to mount the position adjustment member to the fixed member in a state in which a gap height between the fixed member and the position adjustment member is adjustable,
wherein at least one of the plurality of position adjustment mechanisms is provided with a fixedly mounting part, which is configured to mount the position adjustment member to the fixed member in a state in which the gap height is fixed, in place of the gap height adjustment parts at one of the at least three positions.

2. The substrate processing apparatus of claim 1, wherein each of the gap height adjustment parts includes a pull screw part configured to mount the position adjustment member to the fixed member in the state in which the gap height is adjustable, and a push screw part configured to regulate proximity of the fixed member and the position adjustment member in the state in which the gap height is adjustable.

3. The substrate processing apparatus of claim 2, wherein the push screw part of each of the gap height adjustment parts includes a micrometer head.

4. The substrate processing apparatus of claim 2, wherein the pull screw part of each of the gap height adjustment parts includes a clamp lever.

5. The substrate processing apparatus of claim 1, wherein each of the position adjustment mechanisms includes a plurality of horizontal position adjustment parts configured to horizontally move an installation position of the position adjustment member with respect to the fixed member in two directions intersecting each other in a plan view.

6. The substrate processing apparatus of claim 5, wherein each of the horizontal position adjustment parts includes:
a holder having a holding member, which is fixed to the fixed member and disposed at a position facing a side surface of the position adjustment member;
a pull screw part held by the holding member and configured to mount the position adjustment member with respect to the holding member in a state in which the position of the position adjustment member is horizontally movable; and
a push screw part configured to regulate proximity of the holding member and the side surface of the position adjustment member.

7. The substrate processing apparatus of claim 6, wherein the push screw part of each of the horizontal position adjustment parts includes a micrometer head.

8. The substrate processing apparatus of claim 6, wherein the pull screw part of each of the horizontal position adjustment parts includes a clamp lever.

9. The substrate processing apparatus of claim 1, wherein the base is connected to a common lifting mechanism configured to raise and lower the stages supported by the plurality of support columns, respectively.

10. A substrate processing system comprising:
a substrate transfer module including a substrate transfer chamber, and a substrate transfer mechanism disposed in the substrate transfer chamber and including a substrate holder configured to transfer a substrate; and
a substrate processing apparatus as set forth in claim 1, in which the substrate is transferred between the substrate transfer chamber and an inside of the processing container by causing the substrate holder to enter the substrate processing apparatus via a loading/unloading port connected to the vacuum transfer chamber,
wherein the plurality of stages supported on the common base via the plurality of support columns is arranged side by side in a row from the loading/unloading port along an entrance direction of the substrate holder, and
wherein the fixedly mounting part is provided in a position adjustment mechanism of a support column that supports a stage, which is disposed closest to a side of the loading/unloading port of the plurality of stages disposed in a row.

11. The substrate processing system of claim 10, wherein the fixedly mounting part is provided at a position closest to the side of the loading/unloading port among the at least three positions surrounding, in the circumferential direction, the periphery of the support column that supports the stage disposed closest to the side of the loading/unloading port.

12. A method of aligning a stage, which is provided in a substrate processing apparatus and on which a substrate to be processed is placed, the method comprising:
a process of installing, at a preset position above a target stage which is a stage to be aligned and selected from the plurality of stages provided in the substrate processing apparatus as set forth in claim 5, a holding jig in the processing container so as to hold an imaging part configured to image a position specifying mark provided on a top surface of the target stage;
a process of causing the imaging part to be held by the holding jig installed in the processing container;
a process of imaging the position specifying mark on the target stage by the imaging part held at the preset position by the holding jig; and
a process of horizontally aligning the target stage by the horizontal position adjustment parts of the position adjustment mechanism provided on the target stage such that the position specifying mark imaged in the process of imaging is aligned with a target position set within an imaging range of the imaging part.

13. The method of claim 12, wherein the imaging part is a camera-equipped substrate that is capable of being transferred by a substrate holder provided in a substrate transfer mechanism configured to transfer the substrate to be processed with respect to the stage.

14. The method of claim 13, wherein the holding jig includes a cutout portion formed in a region corresponding to a movement path of the substrate holder holding the camera-equipped substrate, so as to avoid interference with the substrate holder when causing the substrate holder holding the camera-equipped substrate to enter the processing container in the process of causing the imaging part to be held by the holding jig.
